(19) United States
(12) Patent Application Publication
(10) Pub. No.: US 2023/0153583 A1
(43) Pub. Date: May 18, 2023

(54) COMPILATION OF NEURAL NETWORKS INTO SUBGRAPHS FOR PROCESSING BY MULTIPLE COMPUTE CIRCUITS

(71) Applicant: Xilinx, Inc., San Jose, CA (US)

(72) Inventors: Ashish Sirasao, San Jose, CA (US); Vishal Kumar Jain, Chhindwara (IN); Sumit Nagpal, Hyderabad (IN)

(73) Assignee: Xilinx, Inc., San Jose, CA (US)

(21) Appl. No.: 17/454,935

(22) Filed: Nov. 15, 2021

(51) Int. Cl. G06N 3/04; G06N 3/10; G06F 8/41

(52) U.S. Cl. CPC G06N 3/049; G06F 8/41; G06N 3/10; G06F 16/9024

(57) ABSTRACT

Processing of a neural network specification includes gathering first layers of a neural network graph into groups of layers based on profiled compute times of the layers and equalized compute times between the groups. Each group is a subgraph of one or more of the layers of the neural network. The neural network graph is compiled into instructions for pipelined execution of the neural network graph by compute circuits. The compiling includes designating, for each first subgraph of the subgraphs having output activations that are input activations of a second subgraph of the subgraphs, operations of the first subgraph to be performed by a first compute circuit and operations of the second subgraph to be performed by a second compute circuit. The compute circuits are configured to execute the instructions.

### TECHNICAL FIELD

The disclosure generally relates to reducing latency and improving throughput of neural networks.

### BACKGROUND

Machine learning is the science of inducing computing systems to act without being explicitly programmed. Classical machine learning includes various clustering and classification techniques, including K-means clustering, linear and logistic regressions, stochastic gradient decent, association rule learning, and the like. Deep learning is a newer frontier in machine learning. Deep learning is a class of machine learning algorithms that uses multiple layers of nonlinear processing units for feature extraction and transformation. Deep learning algorithms can be unsupervised (e.g., pattern analysis) or supervised (e.g., classification). The deep learning algorithm can be implemented using layers of an artificial neural network (ANN) (referred to herein as a “neural network”).

In general, a neural network is a collection of nodes (i.e., the “neurons”) that are connected in a graph. A node in a neural network computes a sum of weighted inputs and adds an optional bias to the sum. The output of the node is a function of the final sum (referred to as an “activation function”). Example activation functions include the sigmoid function, the hyperbolic tangent (tanh) function, the Rectified Linear Unit (ReLU) function, and the identity function. Neural network models are often organized into layers of nodes, which define a specific topology, and corresponding weights and biases. The weights and biases are referred to as network parameters.

In general, a neural network includes an input layer and an output layer and can include many hidden layers between the input and output layers. The layers of a neural network can be densely connected (e.g., each node in a layer is fully connected to all nodes in a previous layer) or sparsely connected (e.g., each node in a layer is connected to only a portion of the nodes in a previous layer). A convolutional neural network (CNN) is a type of deep neural network (DNN) that includes one or more sparsely connected layers, referred to as convolutional layers. A CNN is well-suited for processing image or video data. Other types of DNNs include recurrent neural network (RNNs), which are well-suited for processing speech and text data.

Field programmable gate arrays (FPGAs) have been used to implement circuits that accelerate functions called from software. Circuits that accelerate functions called from software are referred to as hardware accelerators. Some hardware acceleration platforms, such ALVEO platform from Xilinx, Inc., can have FPGA resources that can be configured to include multiple compute circuits that are specifically configured to perform neural network operations (e.g., convolution). The compute circuits can be configured to perform pipelined processing of neural network operations.

Though on-chip memory resources of programmable devices have increased dramatically with each new generation of device, the memory requirements for some applications continue to outpace the available on-chip memory resources of. In neural network applications in which initial and intermediate input and output activations can be stored entirely on-chip and not require movement between off-chip memory and on-chip memory, DPUs can operate very efficiently. However, the memory demands resulting from current trends towards processing high-resolution data (e.g., high-definition and ultra-high definition video) have quickly surpassed supply of on-chip memory. For example, when the size of an activation is large, input activations to the DPU can be tiled and read from off-chip memory. Tiles of intermediate output activations may be written to off-chip memory and then read back into on-chip memory as input activations to subsequent layers. The writing to off-chip memory and reading back into on-chip memory incurs substantial time penalties to DPU performance and leads to non-linearity in latency. “Chip” as used herein refers to a single integrated circuit (IC) semiconductor die, a stack of integrated circuit semiconductor dies, or a package of single and/or multiple IC dies interconnected by a silicon interposer.

### SUMMARY

A disclosed method includes gathering first layers of a neural network graph by a data processing system into groups of layers based on profiled compute times of the layers and equalized compute times between the groups. Each group is a subgraph of one or more of the layers of the neural network. The method includes compiling the neural network graph into instructions for pipelined execution of the neural network graph by a plurality of compute circuits. The compiling includes designating, for each first subgraph of the subgraphs having output activations that are input activations of a second subgraph of the subgraphs, operations of the first subgraph to be performed by a first compute circuit of the plurality of compute circuits and operations of the second subgraph to be performed by a second compute circuit of the plurality of compute circuits. The method includes configuring the compute circuits to execute the instructions.

A disclosed system includes a computer storage arrangement configured with program code that when executed by one or more processors causes the one or more processors to perform operations including gathering first layers of a neural network graph into groups of layers based on profiled compute times of the layers and equalized compute times between the groups. Each group is a subgraph of one or more of the layers of the neural network. The operations include compiling the neural network graph into instructions for pipelined execution of the neural network graph by the compute circuits. The compiling includes designating, for each first subgraph of the subgraphs having output activations that are input activations of a second subgraph of the subgraphs, operations of the first subgraph to be performed by a first compute circuit of the compute circuits and operations of the second subgraph to be performed by a second compute circuit of the compute circuits. The operations include configuring the compute circuits to execute the instructions. The system includes an arrangement of one or more processors coupled to the computer storage arrangement and configured to communicate the program code to another computer storage arrangement in response to download instructions.

Another disclosed method includes gathering layers of the neural network into a subgraph by a data processing system. The layers are serially connected and include layer 1 through layer N, and each layer 1 through layer N specifies generation of respective output activations based on respective input activations. The method includes compiling the neural network graph into instructions for pipelined execution of the neural network graph by a plurality of compute circuits. The compiling includes decomposing the input activations to layer 1 into a plurality of tiles. The compiling includes specifying for first layer processing, tile-by-tile processing of the plurality of tiles and specifying for each layer M processing for 2 ≤ M ≤ (N - 1), tile-by-tile processing of output tiles from layer M as input tiles to layer (M + 1).

Other features will be recognized from consideration of the Detailed Description and Claims, which follow.

### BRIEF DESCRIPTION OF THE DRAWINGS

Various aspects and features of the methods and systems will become apparent upon review of the following detailed description and upon reference to the drawings in which:

FIG. 1 shows an exemplary system in which the disclosed methods can be applied to implement a neural network;

FIG. 2 shows an example of a portion of a neural network graph in which the layers have been gathered into groups of one or more layers to form subgraphs amenable to pipelined processing;

FIG. 3 shows pipelined processing of the subgraphs of FIG. 2 by the exemplary system of FIG. 1;

FIG. 4 shows an example of a neural network graph in which the layers of one branch are grouped into a subgraph for individually computing tiles of input and output activations across the layers of the subgraph, and the layers of another branch are grouped into subgraphs amenable for pipelined processing;

FIG. 5 shows an example in which a set of input activations to a subgraph is tiled for processing by one or more compute circuits, and the tiled output from each layer is passed as tiled input to the next layer of the subgraph for processing;

FIG. 6 shows a flow chart of an exemplary process of forming subgraphs from layers of a neural network for computing tiles across layers and/or pipelined processing of subgraphs; and

FIG. 7 is a block diagram illustrating an exemplary data processing system.

### DETAILED DESCRIPTION

In the following description, numerous specific details are set forth to describe specific examples presented herein. It should be apparent, however, to one skilled in the art, that one or more other examples and/or variations of these examples may be practiced without all the specific details given below. In other instances, well known features have not been described in detail so as not to obscure the description of the examples herein. For ease of illustration, the same reference numerals may be used in different diagrams to refer to the same elements or additional instances of the same element.

Application of the disclosed methods and systems can reduce processing time of neural network applications while enabling linear scaling of performance as the size of neural network increases. The methods and systems provide two decomposition techniques that can be employed alone or in combination to improve performance. One of the techniques involves decomposing a neural network graph into multiple subgraphs for pipelined processing. The second technique involves making a subgraph from serially connected layers of the neural network, decomposing input activations of the subgraph into multiple tiles, and passing tiled output of one layer as tiled input to the next layer for processing. Stitching of tiled outputs is delayed until tiled output from the last layer of the subgraph is generated.

In decomposing a neural network graph into multiple subgraphs for pipelined processing, a compiler gathers layers of a neural network graph into groups of layers based on profiled compute times of the layers. The compiler groups the layers in a manner that equalizes compute times between the subgraphs. That is, the compute time of each subgraph is approximately equal to the compute time of each other subgraph made by the compiler. “Equalize” in this context does not connote strict equality between the compute times, as strict equality would be unlikely given the variability between compute times of the layers in different applications. Rather the compiler can group the layers in a manner that minimizes the differences between compute times of the subgraphs. Once the subgraphs are formed, the compiler generates specifications of neural network operations to be performed by multiple compute circuits of a neural network accelerator. The specifications include instructions for pipelined execution of the neural network graph by the compute circuits. The compiler designates that for each first subgraph of the subgraphs having output activations that are input activations of a second subgraph of the subgraphs, the operations of the first subgraph are to be performed by a first compute circuit of the accelerator and operations of the second subgraph to be performed by a second compute circuit of the accelerator. A configuration tool can then configure the compute circuits of the accelerator with the specifications to perform the neural network operations.

According to the second decomposition technique, throughput can be improved by reducing accesses to off-chip memory by the accelerator. In some neural networks, input and output activations may be larger than the amount of on-chip memory, leading to off-chip memory accesses in communicating activations between layers. Accessing off-chip memory is generally much slower than accessing on-chip memory. According to the disclosed approaches, a group of serially connected layers having activations that do not fit in on-chip memory can be gathered into a subgraph. The compiler can decompose the input activations to the first layer of the subgraph into multiple tiles such that the accelerator has sufficient on-chip memory to store the tiled input activations and output activations of each layer. The tiled output activations from each layer are provided as tiled input activations to the next layer. Notably, the tiled outputs between the first and the next-to-last layer of the subgraph are not stitched. The tiled output of the last layer is stitched.

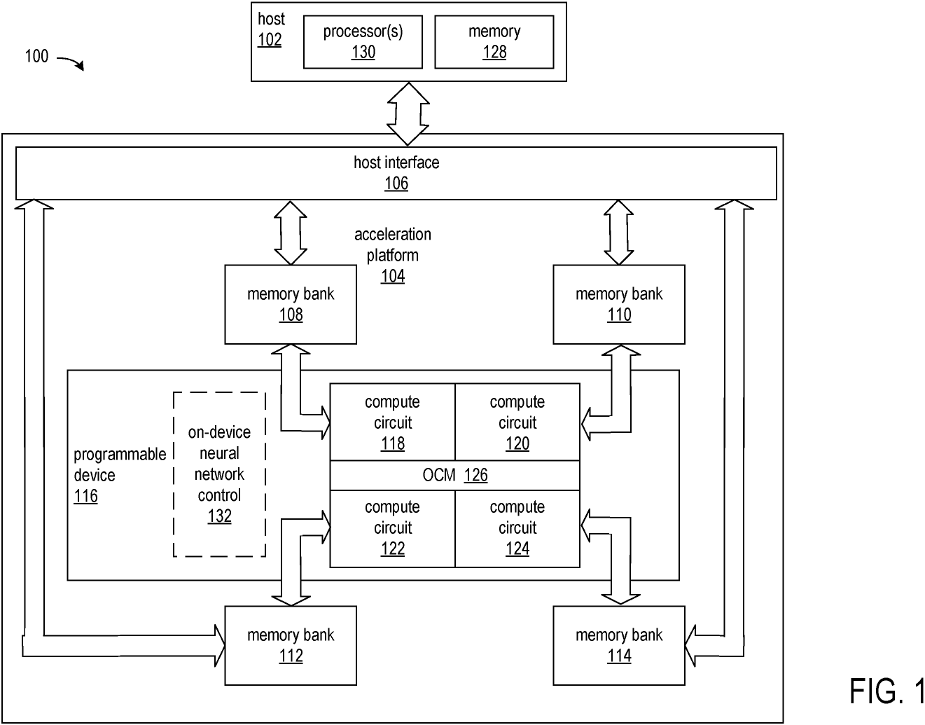

FIG. 1 shows an exemplary system 100 in which the disclosed methods can be applied to implement a neural network. The system includes a host computer system 102 and an acceleration platform 104. The acceleration platform can accelerate computations (e.g., convolutions, etc.) associated with neural network processing, and configuration of the acceleration platform, and initiation of processing can be controlled by the host computer system.

The acceleration platform includes host interface circuitry 106, multiple memory banks 108, 110, 112, and 114, and programmable device 116 disposed on a printed circuit card, for example. The host interface can be a communications bus, such as a PCIe bus. The programmable device 116 of the acceleration platform has programmable logic that can be configured to implement multiple compute circuits 118, 120, 122, and 124. Each compute circuit has access to one of the off-chip memory banks 108, 110, 112, and 114. The programmable device includes on-chip memory (“OCM”) 126 that can be accessed by the compute circuits. In an exemplary implementation, the OCM can be “block RAM” (BRAM) or “ultra RAM” (URAM) that is provided in programmable devices from Xilinx, Inc. Though four compute circuits are shown in the example, many more compute circuits can be configured in the programmable device depending on available resources and application requirements.

The disclosed approaches for decomposing neural network graphs and/or decomposing input activations can be applied to implement a neural network application on the system 100. The layers of a neural network graph can be divided into multiple subgraphs for pipelined processing. In pipelined processing of the subgraphs, the subgraphs are serially connected such that the output activations of each subgraph except the last subgraph are the input activations of the next subgraph of the serial connections. For example, compute circuit 118 can be configured process first input activations according to a first subgraph and produce first output activations, and compute circuit 120 can be configured process the first output activations as second input activations according to a second subgraph and produce second output activations. While the second compute circuit is processing the first output activations as the second input activations, the first compute circuit can be processing another set of input activations according to the first subgraph.

Each of the compute circuits operates out of its associated memory bank. For example, the input activations to compute circuit 118 are stored in memory bank 108, and the output activations produced by compute circuit 118 are written to memory bank 108. To accommodate pipelined processing involving compute circuits 118 and 120 as in the example above, the first output activations in memory bank 108 are moved to memory bank 110 so that compute circuit 120 can use the first output activations as its input activations.

Control over movement of data from one memory bank to the next for processing by different compute circuits can be directed by software fetched from memory 128 and executed on the host processor(s) 130, or directed by an on-device control circuit 132. Both approaches employ direct bank-to-bank transfers of data. That is, data read from one bank is bussed directly and written to another bank. For both host-controlled and on-chip controlled transfer, the data does not pass through host memory.

Input activations to a subgraph of serially connected layers can be decomposed into tiles for inter-layer tile-by-tile processing, which avoids retrieving input activations and writing output activations to the off-chip memory banks between processing of layers of the neural network. The tiled input activations and output activations between layers of the subgraph can remain in the OCM and thereby substantially reduce access times. The input activations to the subgraph are a tensor, and each tile of the input activations is a subset of the activations in which the activations occupy adjacent positions in the tensor (e.g., relative to x, y, and z coordinate positions).

The inter-layer tile-by-tile processing involves decomposing the input activations to the first layer of a subgraph into multiple tiles. The subgraph is comprised of a set of serially connected layers, each of which consumes input and produces output activations too large for OCM. That is, in a subgraph having N layers, each layer L for 1 ≤ L ≤ (N - 1) specifies providing the respective output activations as input activations to layer (L + 1). The tiled input activations are processed tile-by-tile, and each layer produces tiled output activations. The tiled output activations from one layer become the tiled input activations of the next layer. The tiled output activations of the last layer of the subgraph are stitched for subsequent processing according to the neural network.

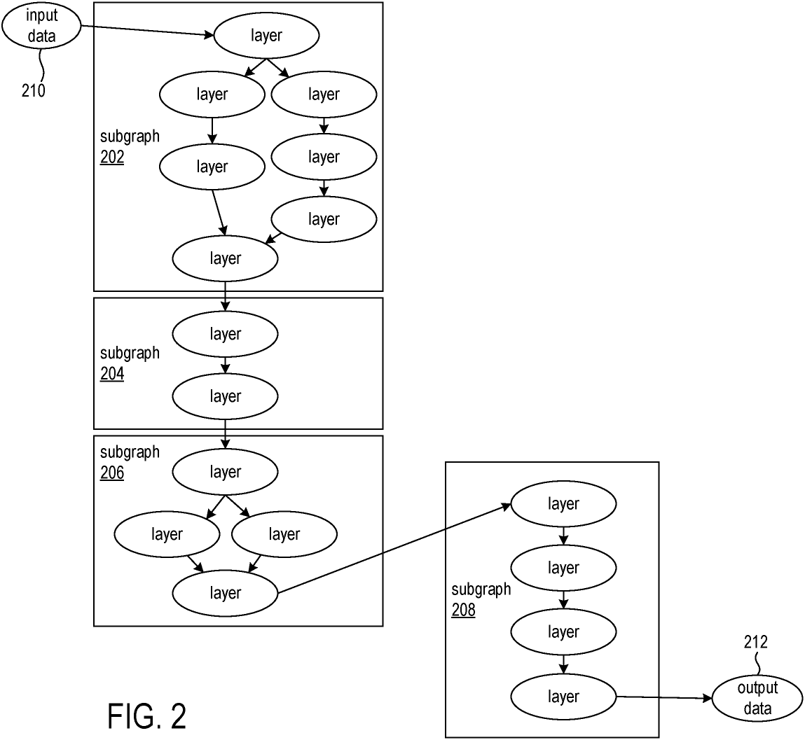

FIG. 2 shows an example of a portion of a neural network graph in which the layers have been gathered into groups of one or more layers to form subgraphs amenable to pipelined processing. The compiler gathers groups of layers of the neural network graph into subgraphs and compiles the subgraphs into a specification for pipelined execution of the subgraphs by multiple compute circuits.

During compilation of the neural network, the compiler gathers layers of the neural network graph into groups of layers based on profiled compute times of the layers. The layers are grouped into subgraphs such that each subgraph has one or more layers, and the compute times of the subgraphs are equalized. In equalizing the compute times, the compiler attempts to minimize differences between compute times of the subgraphs in order to reduce stalling of compute units in the pipeline.

The example shows four subgraphs 202, 204, 206, and 208 of a neural network. The layers and graph structure serve only as an example, which may constitute only a portion of a complete neural network. The input data 210 may be provided from another layer of the neural network graph, and the output data 212 may be provided to yet another layer.

The compiler inputs layer-wise profile data to determine how the neural network graph should be divided into subgraphs. The layer-wise profile data indicate respective execution times of the layers. According to one approach, the layer-wise profile data can be generated by profiling an implementation in which the neural network graph has not been divided into subgraphs for pipelined execution. In profiling the implementation, profiling circuitry can count for each layer, the number of cycles of a clock signal between when the layer initiates processing of a data set and when the layer completes processing of the data set. According to another approach, the profiling circuitry can measure for each layer, the elapsed real time from when the layer initiates processing of a data set to when the layer completes processing of the data set. Once the layer-wise profile data has been generated, the neural network graph can be compiled again using the layer-wise profile data and connectivity between layers to group the layers. According to one approach, the number of subgraphs formed by the compiler is equal to the number of compute circuits available for processing the subgraphs.

In compiling the neural network graph into instructions for execution by the compute circuits, the compiler designates, for each pair of subgraphs in which the first subgraph of the pair has output activations that are input activations of the second subgraph of the pair, operations of the first subgraph to be performed by a first compute circuit of the compute circuits and operations of the second subgraph to be performed by a second compute circuit of the compute circuits. For example, the output activations of subgraph 202 are the input activations subgraph 204 as indicated by the directed edge from the last layer of subgraph 202 to the first layer of subgraph 204. The compiler specifies that the operations of subgraph 202 are to be performed by one compute circuit, and the operations of subgraph 204 are to be performed by another compute circuit.

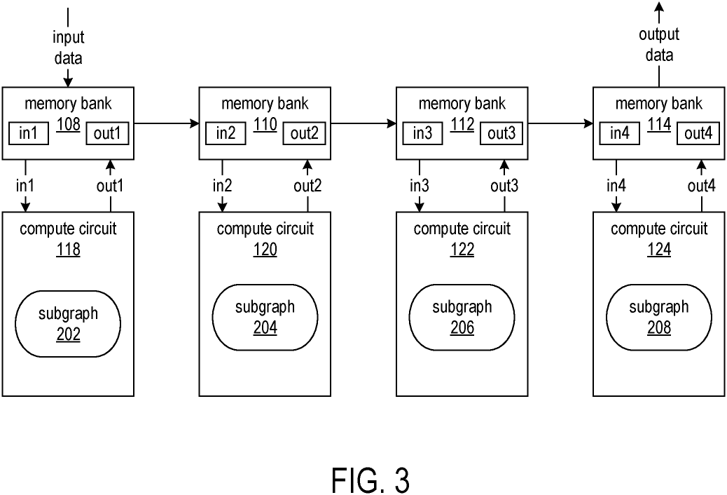

FIG. 3 shows pipelined processing of the subgraphs of FIG. 2 by the exemplary system of FIG. 1. Compute circuit 118 is configured to perform the operations of subgraph 202, compute circuit 120 is configured to perform the operations of subgraph 204, compute circuit 122 is configured to perform the operations of subgraph 206, and compute circuit 124 is configured to perform the operations of subgraph 208.

In processing subgraph 202, compute circuit 118 inputs activations “in1” from and writes output activations “out1” to memory bank 108. Output activations out1 are moved from memory bank 108 to memory bank 110 to be processed as the input activations in2 by compute circuit 120. The output activations can be moved at the direction of the host computer system or on-chip control as indicated above. In processing subgraph 204, compute circuit 120 inputs activations in2 from and writes output activations out2 to memory bank 110. Output activations out2 are moved from memory bank 110 to memory bank 112 to be processed as the input activations in3. In processing subgraph 206, compute circuit 122 inputs activations in3 from and writes output activations out3 to memory bank 112. Output activations out3 are moved from memory bank 112 to memory bank 114 to be processed as the input activations in4. In processing subgraph 208, compute circuit 124 inputs activations in4 from and writes output activations out4 to memory bank 114. Output activations out4 can be provided as output data.

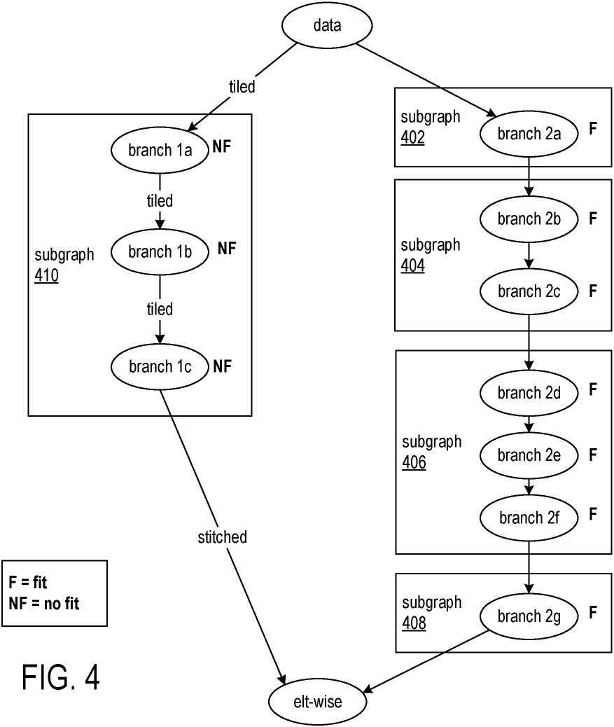

FIG. 4 shows an example of a neural network graph in which the layers of one branch are grouped into a subgraph for individually computing tiles of input and output activations across the layers of the subgraph, and the layers of another branch are grouped into subgraphs amenable for pipelined processing. The branches are indicated as branch 1 and branch 2, and within each branch the layers are labeled alphabetically. The layers of branch 1 are identified as branches 1a, 1b, and 1c, and the layers of branch 2 are identified as branches 2a-2g. The layers of branch 1 are grouped into a subgraph for individually computing tiles of input and output activations across the layers of the subgraph, and the layers of branch 2 are grouped into multiple subgraphs amenable for pipelined processing.

The criteria for selecting layers to include in a subgraph for inter-layer tiled processing are that the layers are serially connected, and the memory required to buffer the input activations and output activations between the serially connected layers is greater than the amount of on-chip memory available.

In the example, branches 1a, 1b, and 1c are serially connected, and for each of the layers, the amount of storage required for the input activations and output activations is greater than the amount of storage available in on-chip memory. That is, the sum of the sizes of the input activations and output activations is greater than the size of on-chip memory. The layers branch 1a, 1b, and 1c are serially connected in that the output activations of branch 1a are the input activations of branch 1b, and the output activations of branch 1b are the input activations of branch 1c.

The compiler groups layers 1a, 1b, and 1c into subgraph 410 and decomposes the input activations to layer 1a into multiple tiles. The size of the tiles is determined based on the amount of on-chip memory available. For example, the tile size is chosen so that the sum of the size of the input tile to branch 1a and the size of the output tile from branch 1a is less than or equal to the amount of on-chip memory available.

Once the input activations to branch 1a have been decomposed into tiles, the tiled output activations from branch 1a are not stitched into a complete set of output activations. Rather, the compiler specifies that the tiled output activations from branch 1a be provided as tiled input activations to branch 1b for processing, and that the tiled activations remain in on-chip memory. This may be referred to as “interlayer tile-by-tile processing.” Similarly, the tiled output activations from branch 1b are provided as tiled input activations to branch 1c. As the output activations from branches 1a and 1b remain tiled and are not stitched, the tiles can remain in on-chip memory, thereby eliminating read and write accesses to off-chip memory for activations between layers.

The compiler can specify that the tiled input activations of a layer be processed by one compute circuit at different times or by multiple compute circuits in parallel. The selection between one or multiple compute circuits can be based on the resources and capabilities of the target programmable device, application performance requirements, etc.

Where the compiler has gathered a group of serially connected layers into a subgraph for interlayer tile-by-tile processing, the compiler generates instructions for stitching the tiled output activations after the last layer of the subgraph. As applied to subgraph 410 in the example of FIG. 4, tiled output activations are output from branch 1c. As branch 1c is the last layer of the subgraph 410, the compiler generates instructions that cause the tiled output activations from branch 1c to be written to a memory bank as a complete set of output activations. The compiler can generate stitch logic that moves the tiled output data from all the banks to one bank, in the process writing each tile to the proper tile relative location in the complete, untiled output.

The subgraphs 402, 404, 406, and 408 can be made by the compiler for pipelined processing as described above.

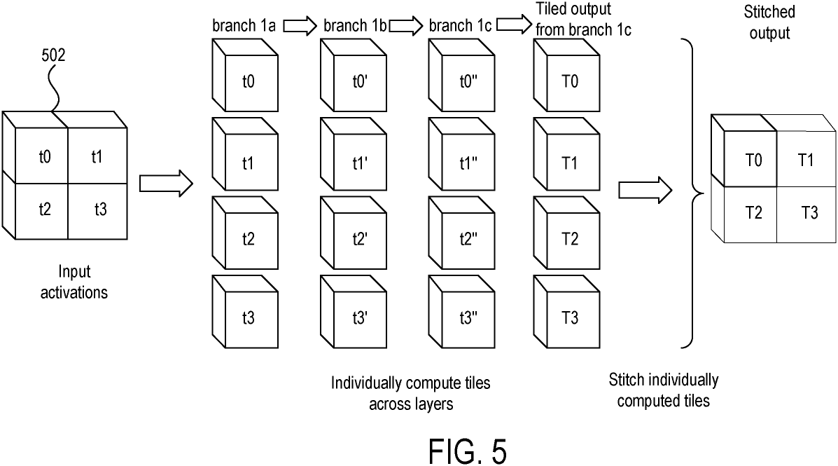

FIG. 5 shows an example in which a set of input activations to the subgraph 410 (FIG. 4) is tiled for processing by one or more compute circuits, and the tiled output from each layer is passed as tiled input to the next layer of the subgraph for processing. The complete set of input activations to the subgraph is shown as input activations 502.

In the example, the compiler has decomposed the input activations into four tiles, t0, t1, t2, and t3. Tiles t0, t1, t2, and t3 are provided as input for the processing of the branch 1a layer of the subgraph. The output from the branch 1a layer are four tiled activations t0′, t1′, t2′, and t3′, and the tiled activations t0′, t1′, t2′, and t3′ are provided as input for the processing of the branch 1b layer of the subgraph. The activations t0′, t1′, t2′, and t3′ are generated by the processing in branch 1a of tiles t0, t1, t2, and t3, respectively. The output from the branch 1b layer are four tiled activations t0″, t1″, t2″, and t3″, and the tiled activations t0″, t1″, t2″, and t3″ are provided as input for the processing of the branch 1c layer of the subgraph. The activations t0″, t1″, t2″, and t3″ are generated by the processing in branch 1b of tiles t0′, t1′, t2′, and t3′, respectively. The output from the branch 1c layer are four tiled activations T0, T1, T2, and T3. The activations T0, T1, T2, and T3 are generated by the processing in branch 1c of tiles t0″, t1″, t2″, and t3″, respectively.

The tiles can be gathered by stitching logic as described above. Alternatively, in an implementation in which the tiles are written to the same memory bank, the tiles can be written to locations that result in complete, untiled output.

The number of compute circuits configured to process the tiled activations can depend on application requirements and resources of the target device. In one example, four compute circuits can be configured to process the tiled activations in parallel. A first compute circuit can perform the processing of branches 1a, 1b, and 1c and stitching of T0, beginning with tile t0 and branch 1a; a second compute circuit can perform the processing of branches 1a, 1b, and 1c and stitching of T1, beginning with tile t1 and branch 1a; a third compute circuit can perform the processing of branches 1a, 1b, and 1c and stitching of T2, beginning with tile t2 and branch 1a; and a fourth compute circuit can perform the processing of branches 1a, 1b, and 1c and stitching of T3, beginning with tile t3 and branch 1a.

In another example, four compute circuits can be configured for pipelined processing of branches 1a, 1b, and 1c and stitching. A first compute circuit can perform processing of branch 1a for tiles t0, t1, t2, and t3 in that order; a second compute circuit can perform the processing of branch 1b of tiles t0′, t1′, t2′, and t3′ as those tiles become available from the first compute circuit; a third compute circuit can perform the processing of branch 1c of tiles t0″, t1″, t2″, and t3″ as those tiles become available from the second compute circuit; and a fourth compute circuit can stitch tiles T0, T1, T2, and T3 as those tiles become available from the third compute circuit.

In another example, 16 compute circuit can be configured for parallel and pipelined processing of branches 1a, 1b, and 1c and stitching. A first compute circuit can perform the processing of branch 1a on tile t0; a second compute circuit can perform the processing of branch 1a on tile t1; a third compute circuit can perform the processing of branch 1a on tile t2; a fourth compute circuit can perform the processing of branch 1a on tile t3; a fifth compute circuit can perform the processing of branch 1b on tile t0′ as that tile becomes available; a sixth compute circuit can perform the processing of branch 1b on tile t1′ as that tile becomes available; a seventh compute circuit can perform the processing of branch 1b on tile t2′ as that tile becomes available; an eighth compute circuit can perform the processing of branch 1b on tile t3′ as that tile becomes available; a ninth compute circuit can perform the processing of branch 1c on tile t0″ as that tile becomes available; a tenth compute circuit can perform the processing of branch 1c on tile t1″ as that tile becomes available; an eleventh compute circuit can perform the processing of branch 1c on tile t2″ as that tile becomes available; a twelfth compute circuit can perform the processing of branch 1c on tile t3″ as that tile becomes available; a thirteenth compute circuit can perform the stitching of tile T0 as that tile becomes available; a fourteenth compute circuit can perform the stitching of tile T1 as that tile becomes available; a fifteenth compute circuit can perform the stitching of tile T2 as that tile becomes available; and a sixteenth compute circuit can perform the stitching of tile T3 as that tile becomes available.

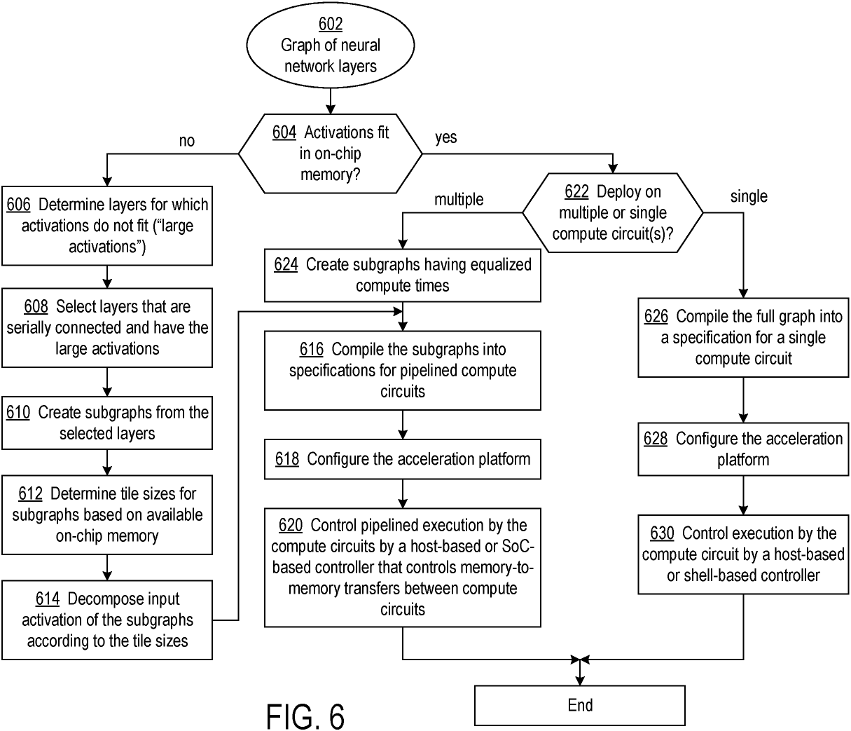

FIG. 6 shows a flow chart of an exemplary process of forming subgraphs from layers of a neural network for computing tiles across layers and/or pipelined processing of subgraphs. A graph 602 of layers of a neural network is generated by a compiler from a neural network specification. The neural network graph has vertices and directed edges. Each vertex represents a layer, and an edge from a first layer to a second layer indicates that the output activations of the first layer are the input activations to the second layer. The compiler can annotate the vertices with profiled processing times and the edges with the sizes (e.g., number of bytes) of the activations.

At decision block 604, the compiler determines whether or not the neural network graph has layers in which the activations do not fit in on-chip memory. In response to determining that the neural network graph has layers whose activations do not fit in on-chip memory, at block 606 the compiler determines the specific ones of the which layers that have the too large activations.

In determining which layers have activations that are too large, the compiler may refer to design specifications that indicate a quantity of on-chip memory available to each compute circuit of the target device. If the sum of the sizes of the input and output activations of a layer is greater than the specified quantity of on-chip memory available to each compute circuit or greater than some threshold less than the amount of available on-chip memory, the layer may qualify for inter-layer tiling with layers that are serially connected to that layer.

At block 608, the compiler selects from the layers identified at block 606, groups of layers that are serially connected. From each group of layers, the compiler creates a subgraph at block 610. Each subgraph has two or more serially connected layers.

At block 612 the compiler determines for each subgraph a suitable tile size. The tile size is calculated based on the available on-chip memory. In addition, the tile size can depend on the kernel size, stride, and other factors related to tensor processing. For each subgraph, the compiler generates instructions at block 614 that decompose the respective set of input activations to the first layer of the subgraph into multiple tiles having the size determined at block 612.

At block 616, the compiler compiles the subgraphs into specifications for inter-layer tile-by-tile pipelined processing of the activations. For each layer in a subgraph, the compiler generates instructions that cause the compute circuits to read input activations from on-chip memory, process the tile according to the layer definition, and write the tile of output activations to on-chip memory.

The instructions generated for first layer processing cause a compute circuit to input the tiled activations from on-chip memory. For each layer after the first layer, a compute circuit reads from on-chip memory, the layer’s input activations which are the tiled activations output from the previous layer. For final processing of the subgraph, the compiler generates instructions that specify stitching of output tiles from the last layer of the subgraph into a complete set of output activations of the subgraph. Depending on implementation requirements, the instructions for stitching can be generated for execution by the host computer system 102 (FIG. 1) or for an on-device control circuit 132 (FIG. 1). The stitching instructions read the final set of tiled activations from on-chip memory and write the tiled activations in a memory bank (e.g., FIG. 1, 108, 110, 112, or 114) at the correct relative addresses.

Once the subgraph(s) and other portions of the neural network neural have been compiled, at block 618 the acceleration platform can be configured to execute the neural network. The configuration can include loading instructions for executing the neural network graph and any subgraphs by the compute circuits. Once configured, at block 620 execution of the neural network can be controlled by a host-based or programmable device-based controller.

In response to determining that the activations of the layers of the neural network graph will fit within on-chip memory, at decision block 622 the compiler determines whether the neural network is to be deployed on a single or on multiple compute circuits. The election may be user-specified or based on device capabilities.

If the neural network is to be deployed on multiple compute circuits and the activations of the layers fit within on-chip memory, the compiler at block 624 the compiler gathers layers of the neural network into subgraphs. Profiled compute times of the layers can be used by the compiler to separate the layers into subgraphs in a manner that equalizes compute times of the subgraphs. The compute time of a subgraph can be estimated to be a sum of the profiled compute times of the layers in the subgraph. Each subgraph includes one or more layers of the neural network graph, and the layers within each subgraph can be connected serially or in parallel. The number of subgraphs formed by the compiler can be equal to the number of compute circuits available for processing the subgraphs.

At block 616, in compiling the subgraphs that were generated for pipelined execution at block 624, the compiler designates which compute circuits are to execute which subgraphs. The compiler specifies that for each subgraph having output activations that are input activations of another subgraph, operations of the first subgraph are to be performed by one compute circuit and operations of the second subgraph to be performed by another compute circuit. At block 624, the compiler also generates instructions for moving activations between memory banks in response to completion of the neural network operations associated with the subgraph. The control for moving activations can be host-based or SoC-based.

In response to determining that the activations of the layers of the neural network will fit in on-chip memory (decision block 604) and determining that the implementation is to be deployed on a single compute circuit (decision block 622), at block 626 the full neural network graph is compiled into instructions for execution by a single compute circuit. At block 628 the acceleration platform can be configured to execute the neural network. The configuration can include loading instructions for executing the neural network graph by the compute circuit. Once configured, at block 630 execution of the neural network can be controlled by a host-based or programmable device-based controller.

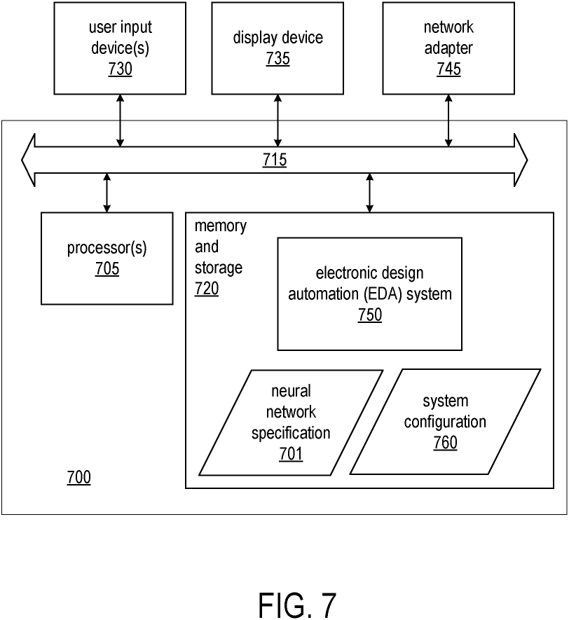

FIG. 7 is a block diagram illustrating an exemplary data processing system (system) 700. System 700 is an example of an EDA system. As pictured, system 700 includes at least one processor circuit (or “processor”) 705, e.g., a central processing unit (CPU), coupled to memory and storage arrangement 720 through a system bus 715 or other suitable circuitry. System 700 stores program code and a neural network specification 701 within memory and storage arrangement 720. Processor 705 executes the program code accessed from the memory and storage arrangement 720 via system bus 715. In one aspect, system 700 is implemented as a computer or other data processing system that is suitable for storing and/or executing program code. It should be appreciated, however, that system 700 can be implemented in the form of any system including a processor and memory that is capable of performing the functions described within this disclosure.

Memory and storage arrangement 720 includes one or more physical memory devices such as, for example, a local memory (not shown) and a persistent storage device (not shown). Local memory refers to random access memory or other non-persistent memory device(s) generally used during actual execution of the program code. Persistent storage can be implemented as a hard disk drive (HDD), a solid state drive (SSD), or other persistent data storage device. System 700 may also include one or more cache memories (not shown) that provide temporary storage of at least some program code and data in order to reduce the number of times program code and data must be retrieved from local memory and persistent storage during execution.

Input/output (I/O) devices such as user input device(s) 730 and a display device 735 may be optionally coupled to system 700. The I/O devices may be coupled to system 700 either directly or through intervening I/O controllers. A network adapter 745 also can be coupled to system 700 in order to couple system 700 to other systems, computer systems, remote printers, and/or remote storage devices through intervening private or public networks. Modems, cable modems, Ethernet cards, and wireless transceivers are examples of different types of network adapter 745 that can be used with system 700.

Memory and storage arrangement 720 may store an EDA application 750. EDA application 750, being implemented in the form of executable program code, is executed by processor(s) 705. As such, EDA application 750 is considered part of system 700. System 700, while executing EDA application 750, receives and operates on neural network specification 701. In one aspect, system 700 executing the EDA compiles the neural network specification 701 into configuration data and instructions 760 for an acceleration platform as described herein. The system 700 can be configured to make the EDA available by an EDA vendor for download to other computer systems or distributed on physical media.

EDA application 750, neural network specification 701, system configuration 760, and any data items used, generated, and/or operated upon by EDA application 750 are functional data structures that impart functionality when employed as part of system 700 or when such elements, including derivations and/or modifications thereof, are loaded into an IC such as a programmable IC causing implementation and/or configuration of a circuit design within the programmable IC.

Various logic may be implemented as circuitry to carry out one or more of the operations and activities described herein and/or shown in the figures. In these contexts, a circuit or circuitry may be referred to as “logic,” “module,” “engine,” “unit” or “block.” It should be understood that logic, modules, engines, units and blocks are all circuits that carry out one or more of the operations/activities. In certain implementations, a programmable circuit is one or more computer circuits programmed to execute a set (or sets) of instructions stored in a ROM or RAM and/or operate according to configuration data stored in a configuration memory.

Though aspects and features may in some cases be described in individual figures, it will be appreciated that features from one figure can be combined with features of another figure even though the combination is not explicitly shown or explicitly described as a combination.

The methods and systems are thought to be applicable to a variety of systems for implementing neural networks. Other aspects and features will be apparent to those skilled in the art from consideration of the specification. The methods and systems may be implemented as one or more processors configured to execute software, as an application specific integrated circuit (ASIC), or as a logic on a programmable logic device. It is intended that the specification and drawings be considered as examples only, with a true scope of the invention being indicated by the following claims.

What is claimed is:

1. A method comprising:
gathering first layers of a neural network graph by a data processing system into groups of layers based on profiled compute times of the layers and equalized compute times between the groups, wherein each group is a subgraph of one or more of the layers of the neural network;
compiling the neural network graph into instructions for pipelined execution of the neural network graph by a plurality of compute circuits;
wherein the compiling includes designating, for each first subgraph of the subgraphs having output activations that are input activations of a second subgraph of the subgraphs, operations of the first subgraph to be performed by a first compute circuit of the plurality of compute circuits and operations of the second subgraph to be performed by a second compute circuit of the plurality of compute circuits; and
configuring the compute circuits to execute the instructions.

2. The method of claim 1, further comprising:
gathering second layers of the neural network into another subgraph, wherein the second layers are serially connected and include layer 1 through layer N, and each layer 1 through layer N specifies generation of respective output activations based on respective input activations;
wherein the compiling includes for the other subgraph:
decomposing the input activations to layer 1 into a plurality of tiles;
specifying for first layer processing, tile-by-tile processing of the plurality of tiles; and
specifying for each layer M processing for 2 ≤M ≤(N - 1), tile-by-tile processing of output tiles from layer M as input tiles to layer (M + 1).

3. The method of claim 2, wherein the compiling includes specifying stitching of output tiles from layer N into a complete set of output activations of the other subgraph.

4. The method of claim 2, wherein:
the compute circuits are programmable logic circuits;
the programmable logic circuits include on-chip memory coupled to the compute circuits; and
the compiling includes specifying that the output tiles from each layer M remain in the on-chip memory for processing as input tiles in layer (M + 1).

5. The method of claim 2, wherein the gathering includes:
determining a quantity of on-chip memory available to a compute circuit; and
determining a tile size of the plurality of tiles of the input activations of layer 1 based on the quantity of on-chip memory available.

6. The method of claim 2, wherein the compiling includes:
determining respective activation sizes of the layers of the neural network; and
wherein the gathering the second layers of the neural network into groups of layers includes limiting the subgraphs to layers having activation sizes greater than a threshold.

7. The method of claim 1, further comprising:
gathering second layers of the neural network into another subgraph, wherein the second layers are serially connected and include a first layer configured to generate first output activations based on first input activations and to provide the first output activations as second input activations to a second layer of the other subgraph;
wherein the compiling includes for the other subgraph:
decomposing the first input activations into a plurality of tiles that includes a first input tile and a second input tile;
specifying first layer processing of the first input tile and the second input tile by one compute circuit at different times or by two compute circuits in parallel; and
specifying, for a first output tile generated from the first layer processing of the first input tile and for a second output tile generated from the first layer processing of the second input tile, second layer processing of the first output tile and the second output tile without stitching the first output tile and the second output tile, wherein the second layer processing is by one compute circuit at different times or by two compute circuits in parallel.

8. The method of claim 1, wherein:
the first and second compute circuits are disposed on a programmable device, the first compute circuit is coupled to a first on-platform memory bank, and the second compute circuit is coupled to a second on-platform memory bank; and
the compiling includes generating instructions executable by a host processor coupled to the programmable device and when executed cause the host processor to initiate moving the output activations from the first on-platform memory bank to the second on-platform memory bank in response to completion of the operations associated with the first subgraph.

9. The method of claim 1, wherein:
the first and second compute circuits are disposed on a programmable device, the first compute circuit is coupled to a first on-platform memory bank, and the second compute circuit is coupled to a second on-platform memory bank; and
the compiling includes generating instructions executable by an on-device controller and when executed cause the on-device controller to initiate moving the output activations from the first on-platform memory bank to the second on-platform memory bank in response to completion of the operations associated with the first subgraph.

10. The method of claim 1, wherein the gathering includes inputting layer-wise profile data that indicate respective execution times of the first layers.

11. The method of claim 10, wherein the profile data specify for each layer a respective number of cycles of a clock signal.

12. The method of claim 10, wherein the profile data specify for each layer a respective elapsed real time.

13. A system, comprising:
a computer storage arrangement configured with program code that when executed by one or more processors causes the one or more processors to perform operations including:
gathering first layers of a neural network graph into groups of layers based on profiled compute times of the layers and equalized compute times between the groups, wherein each group is a subgraph of one or more of the layers of the neural network,
compiling the neural network graph into instructions for pipelined execution of the neural network graph by the compute circuits;
wherein the compiling includes designating, for each first subgraph of the subgraphs having output activations that are input activations of a second subgraph of the subgraphs, operations of the first subgraph to be performed by a first compute circuit of the compute circuits and operations of the second subgraph to be performed by a second compute circuit of the compute circuits, and
configuring the compute circuits to execute the instructions; and
an arrangement of one or more processors coupled to the computer storage arrangement and configured to communicate the program code to another computer storage arrangement in response to download instructions.

14. The system of claim 13, wherein the program code when executed by the one or more processors causes the one or more processors to perform operations including:
gathering second layers of the neural network into another subgraph, wherein the second layers are serially connected and include layer 1 through layer N, and each layer 1 through layer N specifies generation of respective output activations based on respective input activations;
wherein the compiling includes for the other subgraph:
decomposing the input activations to layer 1 into a plurality of tiles;
specifying for first layer processing, tile-by-tile processing of the plurality of tiles; and
specifying for each layer M processing for 2 ≤M≤(N - 1), tile-by-tile processing of output tiles from layer M as input tiles to layer (M + 1).

15. The system of claim 13, wherein the program code for compiling includes program code for specifying stitching of output tiles from layer N into a complete set of output activations of the other subgraph.

16. A method comprising:
gathering layers of the neural network into a subgraph by a data processing system, wherein the layers are serially connected and include layer 1 through layer N, and each layer 1 through layer N specifies generation of respective output activations based on respective input activations;
compiling the neural network graph into instructions for pipelined execution of the neural network graph by a plurality of compute circuits;
wherein the compiling includes:
decomposing the input activations to layer 1 into a plurality of tiles;
specifying for first layer processing, tile-by-tile processing of the plurality of tiles; and
specifying for each layer M processing for 2 ≤M ≤(N - 1), tile-by-tile processing of output tiles from layer M as input tiles to layer (M + 1).

17. The method of claim 16, wherein the compiling includes specifying stitching of output tiles from layer N into a complete set of output activations of the other subgraph.

18. The method of claim 16, wherein:
the compute circuits are programmable logic circuits;
the programmable logic circuits include on-chip memory coupled to the compute circuits; and
the compiling includes specifying that the output tiles from each layer M remain in the on-chip memory for processing as input tiles in layer (M + 1).

19. The method of claim 16, wherein the gathering includes:
determining a quantity of on-chip memory available to a compute circuit; and
determining a tile size of the plurality of tiles of the input activations of layer 1 based on the quantity of on-chip memory available.

20. The method of claim 16, wherein the compiling includes:
determining respective activation sizes of the layers of the neural network; and
wherein the gathering the second layers of the neural network into groups of layers includes limiting the subgraphs to layers having activation sizes greater than a threshold.
